(19) United States
(12) Patent Application Publication
(10) Pub. No.: US 2008/0078983 A1
(43) Pub. Date: Apr. 3, 2008

(54) Layer structures comprising chalcogenide materials

(76) Inventor: Wolfgang Raberg, Sauerlach (DE)

Correspondence Address: SLATER & MATSIL LLP, 17950 PRESTON ROAD, SUITE 1000, DALLAS, TX, 75252, US

(21) Appl. No.: 11/529,564

(22) Filed: Sep. 28, 2006

(51) Int. Cl. H01L 47/00

(52) U.S. Cl. 257/4; 438/900; 257/E29.17

(57) ABSTRACT

The invention provides a layer structure comprising a first layer, the first layer comprising chalcogenide material, and a second layer being deposited onto the first layer, the second layer comprising silver and another material which decreases the mobility of silver atoms or ions or alternately the second layer being a seed layer deposited onto the first layer and the second layer comprising copper and optionally other material, a memory cell comprising such layer structure and the processes for manufacturing the layer structure and the memory cell.

### TECHNICAL FIELD

The invention relates to layer structures used for semiconductor technology.

### BACKGROUND

The development of semiconductor memory technology is essentially driven by the requirement for increasing the performance of the semiconductor memories in conjunction with miniaturization of the feature sizes. However, further miniaturization of the semiconductor memory concepts based on storage capacitors may be difficult due to the large quantity of charge that is required for writing to and reading from the storage capacitors, which leads to a high current demand. Therefore, thought is increasingly being given to new cell concepts that are distinguished by a significantly lower quantity of charge for the writing and reading operation. Semiconductor memories having a resistance memory element that exhibits a bipolar switching behavior are one such new promising circuit architecture.

In order to provide maximum density of memory units, it is desirable to provide a cell field consisting of a plurality of memory cells, which are conventionally arranged in a matrix consisting of column and row supply lines, also called word and bit lines, respectively. The actual memory cell is usually positioned at the crosspoints of the supply lines that are made of electrically conductive material. The word and bit lines are each electrically connected with the memory cell via an upper electrode (also referred to as top electrode) and a lower electrode (also referred to as bottom electrode). To perform a change of the information content in a particular memory cell at the addressed crosspoint, or to recall the content of the memory cell, the corresponding word and bit lines are selected either with a write current or with a read current. To this end, the word and bit lines are controlled by appropriate control means.

There are several memory cells that are able to fit into such memory cell arrangement.

For example, RAM (Random Access Memory) comprises a plurality of memory cells that are each equipped with a capacitor which is connected with a so-called selection transistor. By selectively applying a voltage at the corresponding selection transistor via the word and bit lines, it is possible to store an electric charge as an information unit (bit) in the capacitor during a write process and to recall it again during a read process via the selection transistor. A RAM memory device is a memory with random access, i.e., data can be stored under any particular address and can be read out again under this address later.

Another kind of semiconductor memory is a DRAM (Dynamic Random Access Memory), which comprise in general only one single, correspondingly controlled capacitive element, e.g., a trench capacitor, with the capacitance of which one bit each can be stored as charge. This charge, however, remains for a relatively short time only in a DRAM memory cell, so that a so-called “refresh” must be performed regularly, wherein the information content is written in the memory cell again.

Since it is intended to accommodate as many memory cells as possible in a RAM memory device, one has been trying to realize them as simple as possible and on the smallest possible space, i.e., to scale them. The previously employed memory concepts (flash memories, such as floating gate memories or DRAM) will, due to their functioning based on the storing of charges, presumably meet with physical scaling limits within foreseeable time. Furthermore, in the case of the flash memory concept, the high switching voltages and the limited number of read write cycles, and in the case of the DRAM memory concept the limited duration of the storage of the charge state, constitute additional problems.

The CBRAM (conductive bridging RAM) memory cell, also known as a programmable metallization cell (PMC), may be switched between different electric resistance values by bipolar electric pulsing. In the simplest embodiment, such an element may be switched between a very high (off resistance) and a distinctly lower (on resistance) resistance value by applying short current or voltage pulses. The switching rates may be less than a microsecond. Very high ratios of the off resistance (R(off)) to the on resistance (R(on)) are achieved in the case of the CBRAM cells, due to the very high-resistance state of the solid electrolyte material in the non-programmed state. Typical values are R(off)/R(on)>10⁶ given R(off)>10¹⁰ Ω and an active cell area<1 μm². At the same time, this technology is usually characterized by low switching voltages of less than 100 mV for initiating the erase operation and less than 300 mV for the write operation.

In structural terms, a CBRAM cell is a resistance memory element comprising an inert cathode electrode, a reactive anode electrode and a solid state electrolyte arranged between the cathode and an anode. The term “solid state electrolyte”, as referred to herein, includes all solid state materials in which at least some ions can move under the influence of an electric field.

The chalcogenide materials, usually deposited by means of conventional sputtering processes, usually have an amorphous structure and frequently contain superfluous chalcogenides that are poorly bound so that these weakly bound chalcogenide atoms are conglomerated like clusters and cannot be removed. This leads to the formation of Ag-chalcogenide conglomerates or protrusion defects in the Ag doping and electrode layer. In addition, the etch process of noble metals, such as silver, is difficult as no etch chemistry exists for etching silver.

The roughness of the interface between the layer of a chalcogenide material and the silver layer deposited thereon poses problem not only in the process of manufacturing a CBRAM but generally in all applications in which a silver layer has to be deposited onto the chalcogenide material. For example in the manufacturing of “Phase Change RAM” (Abb.: PCRAM or PRAM), in a special form also designated as “Ovonics Unified Memory,” “OUM” or “chalcogenide RAM” the conglomerates or protrusion defects can arise when a silver layer is deposited onto the chalcogenide materials.

For these and other reasons, there is a need for the present invention as set forth in the following in the embodiments.

### SUMMARY OF THE INVENTION

In accordance with an embodiment of the invention layer structures are provided having a first layer containing chalcogenide material and a second layer deposited onto the first layer, wherein the second layer contains metal atoms or ions. Further, in accordance with an embodiment of the invention processes of manufacturing layer structures are provided.

In accordance with an embodiment of the present invention, there is provided a layer structure comprising a first layer containing a chalcogenide material and a second layer containing silver and a material which decreases the mobility of silver atoms or ions.

In accordance with another embodiment of the present invention there is provided a layer structure containing a first layer containing a chalcogenide material and a second layer deposited onto the first layer, wherein the second layer is a seed layer containing copper and optionally other materials.

In accordance with another embodiment of the present invention there is provided a memory cell with a first layer containing a chalcogenide material and a layer deposited onto the first material, the second layer containing silver and another material which decreases the mobility of silver atoms or ions.

In accordance with another embodiment of the invention there is provided a memory cell having a first layer containing a chalcogenide material and a second layer deposited thereon, wherein the second layer is a seed layer containing copper and optionally other materials.

In accordance with yet another embodiment of the invention there is provided a process of manufacturing a layer structure having a first layer containing a chalcogenide material a second layer containing silver and a material which decreases the mobility of silver atoms or ions.

In accordance with another embodiment of the invention there is provided a process of manufacturing a layer structure having a first layer which contains a chalcogenide material and a second layer, which is a seed layer containing copper and optionally other materials.

In accordance with another embodiment of the invention there is provided a process of manufacturing a memory cell having a first layer containing a chalcogenide material and a second layer containing silver and a material which decreases the mobility of silver atoms or ions.

In accordance with another embodiment of the invention there is provided a process of manufacturing a memory cell having a first layer containing a chalcogenide material and a second layer deposited thereon, wherein the second layer is a seed layer containing copper and optionally other materials.

### BRIEF DESCRIPTION OF THE DRAWINGS

In the following, the invention will be explained in more detail with reference to the exemplary embodiments and drawing, in which:

FIG. 1 shows the chalcogenide material-silver layer interface;

FIG. 2 shows a cross sectional view of a layer structure according to the first aspect of the present invention;

FIG. 3 shows a cross sectional view of a layer structure according to second aspect of the present invention;

FIG. 4 shows a process for manufacturing a layer structure, in accordance to the fifth aspect of the present invention;

FIG. 5 shows a process for manufacturing a layer structure, in accordance to the sixth aspect of the present invention;

FIG. 6 shows a process for manufacturing a memory cell according to an embodiment of the present invention, in accordance to the seventh aspect of the present invention; and

FIG. 7 shows a process for manufacturing a memory cell, in accordance to the eighth aspect of the present invention.

### DETAILED DESCRIPTION OF ILLUSTRATIVE EMBODIMENTS

As stated above, in accordance with an embodiment of the present invention, there is provided a layer structure comprising a first layer comprising chalcogenide material and a second layer containing silver and further containing another material which decreases the mobility of silver atoms or ions.

The term “decreasing the mobility silver ions” as used hereinafter means that the mobility of the silver ion is decreased with the mobility of silver atoms or ions in a layer consisting e.g., essentially of silver.

According to an embodiment of the present invention, the layer containing chalcogenide material may be a layer consisting essentially of a chalcogenide material or a layer containing a chalcogenide material and having other materials such as metal ions to serve, for example, as a solid state electrolyte. The layers consisting essentially of chalcogenide materials may be used for example in a PCRAM memory cells, wherein the layer comprising chalcogenide materials doped with metal ions may be used for example in a CBRAM memory cell. However, other applications of layers are also possible and fall within the scope of the present invention.

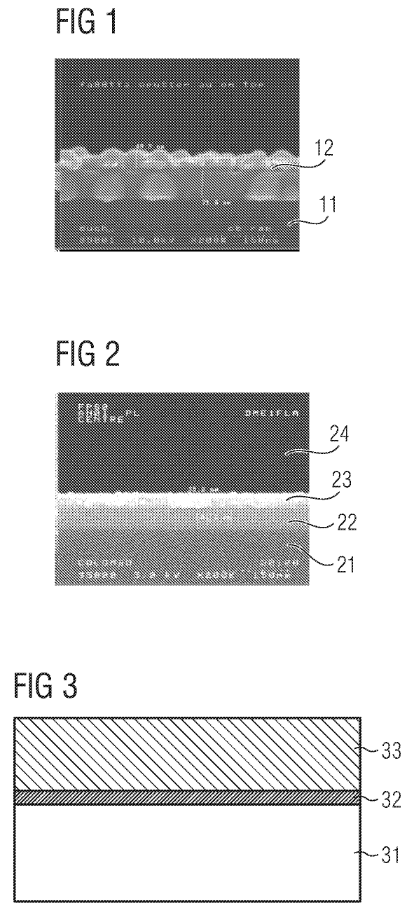

In an embodiment of the invention as shown in FIG. 2, there is provided a layer of a chalcogenide material 22 on or above a carrier 21, e.g., a substrate, e.g., made of silicon oxide, and a further layer 23 containing silver and being deposited onto the chalcogenide material 22. As shown in FIG. 2 other layers such as the layer 24, may also be present in some applications. The purposes of the other layer 24 may be for example to act as an anode in a CBRAM memory cell or as a heating contact in a PCRAM memory cell. The layer 24, as shown in FIG. 2, consists essentially of silver in order to make clear the advantages of the present invention when comparing the layer structure of the present invention to the layer structure as shown in FIG. 1. In FIG. 1, for example, the layer 11 consists essentially of a chalcogenide material and the layer 12 consists essentially of elementary silver. As shown in FIG. 1, the deposition of silver directly onto the chalcogenide material usually leads to conglomerates or protrusion defects on the interface between the layer of the chalcogenide material and the silver layer. Therefore, a much smoother interface between the layers 22/23 and 23/24 can be obtained by depositing a layer 23 containing silver and further containing another material which decreases or essentially inhibits the mobility of silver atoms or ions.

In one embodiment of the invention the layer 23 consists essentially of silver (Ag) and another material which decreases the mobility of silver ions. When silver is deposited together with another material which decreases the mobility of silver atoms the roughness of the surface is reduced and smoother surfaces may be obtained.

In another embodiment of the invention there is provided a chalcogenide layer 22 and the layer 23 thereon, wherein the layer 23 contains silver (Ag) and tantalum (Ta).

According to another embodiment of the invention the Ag-bearing layer 23 consists essentially of Ta and Ag. In a further embodiment of the invention the Ag-bearing layer 23 consists essentially of Ta and Ag, wherein content of Ta being the range of about 50 atomic % to about 3 atomic %.

According to another embodiment of the invention the layer structure comprises a further layer deposited on or above the Ag-bearing layer 23, the further layer 24 containing Ag. Such a further layer 24 may, for example, have a function of an anode in a, for example, CBRAM memory cell or a heating contact in a PCRAM memory cell. However, this layer may not necessarily be present since the Ag-bearing layer 23 can function both as an anode or as a heating contact.

In another embodiment the further layer 24 consists essentially of Ag. This has an advantage in that conventional processes and materials can be used to prepare the anode of a for example CBRAM memory cell.

According to another embodiment of the present invention the chalcogenide layer 22 typically contains a chalcogenide material which is selected from the group consisting of compositions of sulfur, selenium and/or tellurium with semiconductors or metals such as arsenic, germanium, bismuth, nickel, silicon (e.g., silicon sulfur or silicon selenium), and zinc.

In another embodiment of the present invention the chalcogenide material for the chalcogenide layer 22 is selected from the group consisting of GeSe and GeS.

The thickness of the Ag-bearing layer 23 according to one embodiment of the present invention is in the range of about 10 nm to about 100 nm. According to another embodiment of the present invention, the thickness of the Ag-bearing layer 23 is less than 100 nm. This Ag-bearing layer 23 is typically in a physical contact with solid state electrolyte material, in other words with the chalcogenide layer 22. In case that no further layers such as layer 24 are present, it may be desirable to grow the Ag-bearing layer 23 to a thickness of more than 100 nm.

As shown in FIG. 2, three layers 21, 22, 23 are provided and the layer 24 is an optional layer which may be present if desired but is not necessary in view of the present invention. If desired, not only one but a plurality of further layers can be provided, the further layers being deposited onto the Ag-bearing layer 23.

By providing the Ag-bearing layer 23 onto the chalcogenide layer 22 the interface of the layers 22/23 can provide a thickness uniformity of about ± about 1%.

In another embodiment of the invention, as shown in FIG. 3, there is provided a layer structure containing a first layer 31 containing chalcogenide material and a second layer 32 being a seed layer deposited onto the first layer.

The seed layer contains 32 typically copper (Cu) and optionally other material. By providing the seed layer 32 the smoothness and the thickness uniformity of the interface between the chalcogenide material and the seed layer is increased. It is possible to obtain a smoothness of the interfaces between the seed layer and the layer containing a chalcogenide material comparable to the interface of the layers 22/23 of FIG. 2.

In one embodiment, the seed layer 32 consists of Cu and a further material selected from the group consisting of Ta, W, Ti, Mo, and Ru. If desired, it is possible to cause either a partial or a complete diffusion of Cu from the seed layer 32 into the first layer 31, which comprises a chalcogenide material. If, for example, seed layer 32 is made essentially of copper and ruthenium, after the complete diffusion of copper only a ruthenium layer would be left on the surface of the first layer 31.

In another embodiment of the invention, seed layer 32 contains Cu and Ru. Further materials are not necessary and a layer consisting essentially of Cu is sufficient to provide a smooth interface between the solid state electrolyte and the reactive anode. Nevertheless, it may be desirable to include further materials into the seed layer 32 for particular purposes and application.

The chalcogenide material used for the first layer 31 in the second embodiment of the present invention is typically a chalcogenide material which is selected from the group consisting of compositions of sulfur, selenium and/or tellurium with metals such as arsenic, germanium, bismuth, nickel, and zinc.

In another embodiment of the present invention the chalcogenide material for the first layer 31 is selected from the group consisting of GeSe and GeS.

The thickness of the seed layer 32 is in the range of about 0.3 nm to about 50 nm, e.g., in the range of about 0.3 nm to about 5 nm. According to another embodiment of the present invention the thickness of the seed layer 32 is less than 100 nm.

By providing a seed layer 32 onto the layer of a chalcogenide material it is possible to obtain a thickness uniformity of ± about 10% of the seed layer 32. It is then possible to grow a further layer 33 onto the seed layer 32, by for example electro-chemical plating or by sputtering. The layer 33 can, for example, serve as an anode in a CBRAM cell or as a heating contact in the PCRAM cell.

According to the third embodiment of the invention there is provided a memory cell containing a chalcogenide material and a layer deposited onto the chalcogenide material, the layer containing silver and another material which decreases or essentially inhibits the mobility of silver atoms or ions. The memory may be any memory in which a chalcogenide material is used. Such memory cells are for example CBRAM memory cells or PCRAM memory cells.

In structural terms, a CBRAM cell is a resistance memory element containing an inert cathode electrode, a reactive anode electrode and a solid state electrolyte disposed between the cathode and an anode. The term “solid state electrolyte”, as referred to herein, includes chalcogenide material in which at least some ions can move under the influence of an electric field.

The solid state electrolyte used in the CBRAM cells is typically a chalcogenide-metal compound(s) (also referred to as chalcogenide material), containing ions of an electrically conducting material, which is usually silver. Chalcogenide materials that can be used are compositions of sulfur, selenium and/or tellurium with metals such as arsenic, germanium, bismuth, nickel, and zinc. The chalcogenide material/silver ion composition may be obtained by photodissolution of a silver layer, by co-depositing chalcogenide material and silver (or other materials), by sputtering using a source containing the chalcogenide and the metal, or by other processes, such as doping, thermal dissolution, etc.

In order to obtain a solid state electrolyte for the CBRAM cell starting from chalcogenide materials, metal ions have to be introduced into the chalcogenide network. Silver is usually introduced into chalcogenide material by illuminating a thin silver film deposited onto the chalcogenide material typically with light of wavelength less than 500 nanometers. If sufficient silver is present, the process results in the saturation of the chalcogenide material with silver through the formation of a silver compound with the chalcogenide material. Such silver compounds may or may not have defined stoichiometry. In some cases the silver content in the chalcogenide material may be below the saturation level, but in other instances it is desirable to fully saturate the chalcogenide material with silver or other metal ions. The content of the metal ions in the chalcogenide material can be controlled by the thickness of the silver layer which is subjected to photodissolution.

Through application of an electric field between the two electrodes, it is possible to produce a conductive path (clearly a conductive filament) through the carrier material and to clear it away again. Depending on the polarity of the electrical pulses applied between anode electrode and cathode electrode, the reactive anode electrode can be dissolved electrochemically and the metal-rich deposits on the carrier material are intensified, which then leads to an electrically conductive connection between the electrodes. By reversing the electrical pulse, the electrically conductive connection is resolved and the metal ions are deposited from the carrier material on the anode electrode.

As the reactive anode electrode is dissolved electrochemically to form the metal-rich deposits in the solid state electrolyte the typically used anode is made of silver or comprises silver, in the case the silver ions are also present in the chalcogenide material. The cathode used in a CBRAM cell can be made of any conducting material since the cathode is inert and does not participate in the electrochemical processes. Typical materials for the cathode are, for example, W, TiN, TiW, TiAlW, even though any conductive material can be used.

The surfaces of the chalcogenide material that are deposited by means of sputtering processes have an amorphous structure and frequently contain superfluous chalcogenides that are poorly bound so that these weakly bound chalcogenide atoms are conglomerated like clusters and cannot be removed which leads to the formation of Ag-chalcogenide conglomerates or protrusion defects in the Ag doping and electrode layer. In addition, the etch process of noble metals is difficult as no etch chemistry exists for etching silver for example. It is, thus, difficult to obtain a homogeneous, planar anode for the CBRAM cells using silver.

PCRAM memory cells, on the other hand, use the unique behavior of chalcogenide glass. In the PCRAM memory cells a chalcogenide material is disposed between two electrodes. The internal organization of chalcogenide glass can be structurally altered by the application of heat from for example crystalline state into an amorphous state. The crystalline and amorphous states have different typical electrical resistivity values and this forms the basis by which data is stored. The amorphous, high resistance state is used to represent a binary “1”, and the crystalline, low resistance state represents a “0.”

PCRAM can be constructed in a number of different ways. In one process, diodes are used as selection elements instead of transistors. It is also possible to arrange the PCRAMs into so called cross-point memory cells, which are composed simply of a self-aligned chalcogenide cells sandwiched between the address lines.

According to the third embodiment of the present invention, there is provided a memory cell with a layer structure containing a layer structure containing a first layer containing chalcogenide material and a second layer containing silver and another material which decreases or essentially inhibits the mobility of silver atoms or ions. Further layers may also be present, if necessary. Typically, there is also a layer which serves as an anode and a layer serving as a cathode for the memory cell. The cathode layer is typically arranged on the one side of the layer containing a chalcogenide material and an anode on the opposite side. However, the anode can also be the second layer containing silver and further containing another material which decreases the mobility of silver atoms or ions, or another layer can be deposited onto the layer containing silver and another material which decreases the mobility of silver atoms or ions to serve as an anode.

In one embodiment of the invention the memory cell comprises the second layer, which contains silver (Ag) and tantalum (Ta).

According to another embodiment of the invention, the memory cell comprises the second layer which consists essentially of Ta and Ag. In a further embodiment of the invention the memory cell comprises the second layer which consists essentially of Ta and Ag, wherein the content of Ta being the range of about 50 atomic % to about 3 atomic %.

According to another embodiment of the invention the memory cell has a layer structure containing a third layer deposited onto the second layer, the third layer consisting essentially of Ag. The third layer may, for example, have a function of an anode in a, for example CBRAM memory cell or a heating contact in a PCRAM memory cell. However, as stated above, the third layer may not necessarily be present since the second layer can have a function both of an anode and of a heating contact.

According to another embodiment of the present invention the first layer of the memory cell contains typically a chalcogenide material which is selected from the group consisting of compositions of sulfur, selenium and/or tellurium with metals such as arsenic, germanium, bismuth, nickel, and zinc.

In another embodiment of the present invention the chalcogenide material for the first layer of the memory cell is selected from the group consisting of GeSe and GeS.

The thickness of the second layer of the memory cell is according to one embodiment of the present invention in the range of about 10 nm to about 100 nm. According to another embodiment of the present invention the thickness of the second layer of the memory cell is less than 100 nm. If desired, it is possible to grow the second layer of the memory cell to a thickness which is more than 100 nm especially in the cases when there are no further layers deposited onto the second layer of the memory cell and the second layer has the function of an anode or of a heating contact.

In one embodiment of the present invention the memory cell is a CBRAM memory cell.

In another embodiment of the present invention the memory cell is a PCRAM memory cell.

In the fourth embodiment of the invention, there is provided a memory cell having a layer structure containing a first layer, containing chalcogenide material, and a second layer, which is a seed layer deposited onto the first layer.

The seed layer of the memory cell, according to the fourth embodiment of the present invention, comprises typically copper (Cu) and optionally other materials. By providing the seed layer, the smoothness and the uniformity of the interface between the chalcogenide material and the seed layer is increased.

In accordance to an embodiment with regard to the fourth embodiment of the invention, the seed layer consists of Cu and a further material selected from the group consisting of Ta, W, Ti, Mo, and Ru. If desired, it is possible to cause either a partial or a complete diffusion of Cu from the seed layer into the first layer containing chalcogenide material. If, for example, the seed layer is made essentially of copper and ruthenium, after the diffusion of copper only a ruthenium layer would be left on the surface of the first layer.

In another embodiment of the invention the second layer contains Cu and Ru. Further materials are not necessary and a layer consisting essentially of Cu is sufficient to provide a smooth interface between the solid state electrolyte and the reactive anode. Nevertheless, it may be desired to include further materials into the second layer for particular purposes and application.

The chalcogenide material used for the first layer in the fourth aspect of the present invention is typically a chalcogenide material which is selected from the group consisting of compositions of sulfur, selenium and/or tellurium with metals such as arsenic, germanium, bismuth, nickel, and zinc.

In another embodiment of the present invention the chalcogenide material for the first layer is selected from the group consisting of GeSe and GeS.

The thickness of the seed layer is in the range of about 0.3 nm to about 50 nm. According to another embodiment of the present invention the thickness of the seed layer is less than 1 nm.

By providing a seed layer onto the layer of a chalcogenide material, it is possible to obtain a thickness uniformity of ± about 1% of the seed layer. It is then possible to grow one or more further layers onto the seed layer, by, for example, electrochemical plating or by sputtering. The further layer(s) can, for example, serve as an anode in a CBRAM cell or as a heating contact in the PCRAM cell.

In one embodiment of the present invention the memory cell is a CBRAM memory cell.

In another embodiment of the present invention the memory cell is a PCRAM memory cell.

In the following, many specific details of the invention are described below with reference to the processes of manufacturing the layer structures of the present invention and the memory cells containing the layer structures according to the present invention. A person skilled in the art will, however, understand that the present invention may have additional embodiments, be used in connection with materials not described therein or that the invention may be practiced without several of the details described below.

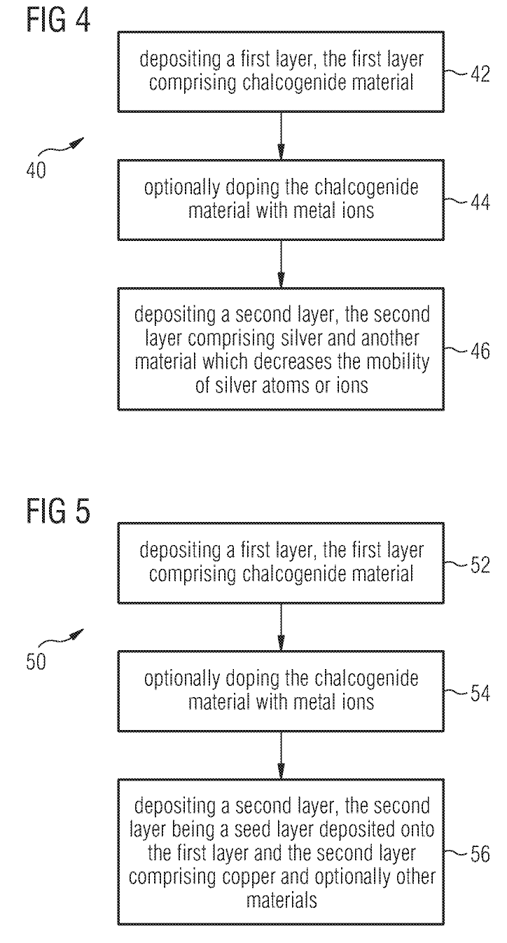

In the fifth embodiment of the present invention there is provided a process of manufacturing a layer structure of the first aspect of the present invention as shown in flow diagram 40 in FIG. 4.

The layer structure according to the first embodiment of the present invention may be manufactured, for example, by a conventionally process of depositing a first layer containing a chalcogenide material (process 42) and if desirable patterning the chalcogenide material. The deposition of the chalcogenide material is done using for example reactive sputtering techniques with targets selected from, for example, S, Se and/or Te on the one hand and germanium, bismuth, nickel, and/or zinc on the other hand.

The layer thickness of the chalcogenide material is approximately 50 nm-100 nm in this particular example.

If desired a metal, e.g., silver may be introduced into the chalcogenide material (process 44) in order to form a solid state electrolyte. The introduction of silver can take place either by illuminating a thin silver film deposited onto the chalcogenide material with light of wavelength of typically less than 500 nm or in a sputter process by using an Ag sputter target. After the formation of the solid state electrolyte, this layer may be cleaned by RF-plasma, if necessary.

Onto the layer of the solid state electrolyte a second layer containing silver (Ag) and another material which decreases the mobility of silver atoms or ions is deposited (process 46). The deposition of the layer containing silver (Ag) and another material which decreases the mobility of silver atoms or ions can be carried out by co-sputtering using a silver target and a target of material which decreases the mobility of silver atoms or ion or by using a compound target. For example, when the silver layer contains Ta, either the co-sputtering using a silver target and a tantalum target can be performed or a sputtering process using an AgTa-compound target.

According to another embodiment of the invention, the layer structure of the first embodiment of the present invention comprises a layer containing silver and another material which decreases the mobility of silver atoms or ions. This layer consists essentially of Ta and Ag. Thus, the deposition of the layer containing silver and Ta may be done by a process of co-sputtering using an Ag and a Ta sputter targets. In a further embodiment of the invention resultant layer containing silver Ag and Ta, the content of Ta being in a range of about 50 atomic % to about 3 atomic % referred to the entire weight if the layer.

The thickness of the layer containing silver and another material is in the range of about 10 nm to about 100 nm. According to another embodiment of the present invention, the thickness of the layer containing silver and another material is less than 100 nm. In the case that no further layers are deposited for an anode, it can be also desirable to grow the layer 23 to a thickness which is more than 100 nm.

If necessary, a further layer can be then deposited and structured using conventional processes. The materials for further layers can be for example silver or copper if the layer structure is to be used in a CBRAM cell or any of the conventional conductive materials for the heating contact in a PCRAM cell.

In the sixth embodiment of the present invention, there is provided a process of manufacturing a layer structure of the second embodiment of the present invention as shown in a flow diagram 50 of FIG. 5.

The layer structure according to the second aspect of the present invention can be manufactured for example by a conventional process of depositing a chalcogenide material (process 52) and, if desired, patterning the chalcogenide material. The deposition of the chalcogenide material is carried out using for example reactive sputtering techniques with targets selected from for example S, Se and/or Te on the one hand and germanium, bismuth, nickel, and/or zinc on the other hand.

In another embodiment of the present invention, the chalcogenide material for the chalcogenide layer 22 is selected from the group consisting of GeSe and GeS.

The layer thickness of the chalcogenide material is approximately 50 nm to 100 nm in this particular example.

If desired, a metal, e.g., silver, may be introduced into the chalcogenide material (process 54) in order to form a solid state electrolyte. The introduction of silver can take place either by illuminating a thin silver film deposited onto the chalcogenide material with light of wavelength of typically less than 500 nm or in a sputter process by using an Ag sputter target. After the formation of the solid state electrolyte, this layer may be cleaned by RF-plasma, if necessary.

Onto the layer of the chalcogenide material, a seed layer is deposited (process 56). The seed layer comprises typically copper (Cu) and optionally other material(s).

In one embodiment the seed layer consists of Cu and a further material selected from the group consisting of Ta, W, Ti, Mo, and Ru.

The deposition of the seed layer may be carried out by sputtering using a Cu-target if a layer which consists essentially of Cu is desired. Alternatively, the deposition can be carried out using co-sputtering with a Cu-target and one of more targets of other materials if the seed layer should contain further materials. Alternately, the deposition can be carried out using a compound target, such as CuRu if a layer contains Cu and Ru is desired. If the seed layer consists essentially of copper a third layer having a composition different from the seed layer is provided.

After the deposition of the seed layer and optionally structuring the seed layer, a partial or a complete diffusion of Cu from the seed layer into the chalcogenide layer can be performed by, for example, temperature treatment. In an alternative embodiment of the invention, a complete diffusion of Cu from the seed layer into the chalcogenide layer can be performed by photodissolution. If, for example, the seed layer is made essentially of copper and ruthenium, after the diffusion of copper only a ruthenium layer as a seed would be left on the surface of the chalcogenide layer.

In another embodiment of the invention, the seed layer contains Cu and Ru. Further materials are not necessary and a layer consisting essentially of Cu is sufficient to provide a smooth interface between the solid state electrolyte and the reactive anode. Nevertheless, it may be desirable to include further materials into the seed layer for particular purposes and application.

The thickness of the seed layer is in the range of about 0.3 nm to about 500 nm. According to another embodiment of the present invention the thickness of the seed layer is less than 100 nm.

By providing a seed layer onto the layer of a chalcogenide material, it is possible to obtain a thickness uniformity of ± about 1% of the seed layer. It is then possible to grow a further layer(s) onto the seed layer by, for example, electro-chemical plating or by sputtering. The further layer(s) can, for example, serve as an anode in a CBRAM cell or as a heating contact in the PCRAM

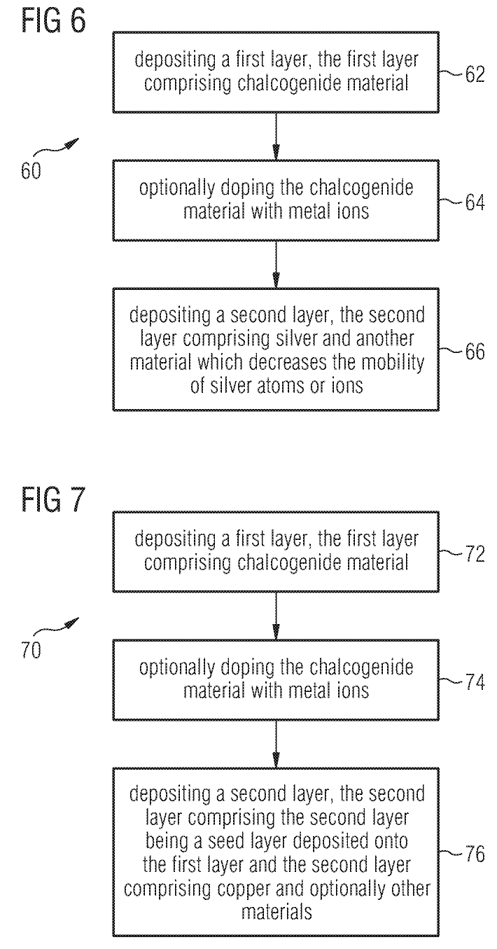

According to the seventh aspect of the present invention a process of manufacturing a memory cell is provided as shown in a flow diagram 60 of FIG. 6.

For example, in accordance with an embodiment of the invention, a metallization for the cathode may be deposited on a substrate and patterned using lithographic techniques. By way of example, tungsten, TiN, TiW, TiAlN or others may be used as an electrode material for the cathode.

After patterning the cathode, the chalcogenide material is deposited and patterned (process 62). The deposition of the chalcogenide material is done using, for example, reactive sputtering techniques with targets selected from for example S, Se and/or Te on the one hand and germanium, bismuth, nickel, and/or zinc on the other hand. The layer thickness of the chalcogenide material is approximately 50 nm to 100 nm in this particular example. The size of the cell can be approximately 1 μm×1 μm, but both larger and smaller cells can also be prepared using the process described herein.

Thereafter, if desired, a metal, e.g., silver, may be introduced into the chalcogenide material (process 64) in order to form a solid state electrolyte. The introduction of silver can take place either by illuminating a thin silver film deposited onto the chalcogenide material with light of wavelength of typically less than 500 nm or in a sputter process by using an Ag sputter target. After the formation of the solid state electrolyte, this layer may be cleaned by RF-plasma, if necessary.

Onto the chalcogenide layer, a layer containing a silver layer containing silver (Ag) and another material which decreases the mobility of silver atoms or ions is deposited (process 66). The deposition of the layer containing silver (Ag) and another material which decreases the mobility of silver atoms or ions can be done by co-sputtering using a silver target and a target of material which decreases the mobility of silver atoms or ion or by using a compound target. For example, when the silver layer contains Ta, either the co-sputtering using a silver target and a tantalum target can be performed or a sputtering process using an AgTa-compound target.

According to another embodiment of the invention, the layer structure of the first embodiment of the present invention comprises the layer containing silver and another material which decreases the mobility of silver atoms or ions consists essentially of Ta and Ag. Thus, the deposition of the layer containing silver and Ta is carried out by a process of co-sputtering using an Ag and a Ta sputter targets. In a further embodiment of the invention, the resultant layer containing silver Ag and Ta having the content of Ta in a range of about 50 atomic % to about 3 atomic % referred to the entire weight if the layer.

The thickness of the layer containing silver and another material is in the range of about 10 nm to about 100 nm. According to another embodiment of the present invention, the thickness of the layer containing silver and another material decreases the mobility of silver atoms or ions is less than 100 nm. In case that no further layers are deposited for an anode, it can be also desirable to grow the layer containing silver and another material decreases the mobility of silver atoms or ions to a thickness which is more than 100 nm.

If necessary, a further layer can be then deposited and structured using conventional processes. The materials for further layer can be for example silver, copper if the layer structure is to be used in a CBRAM cell or any of the conventional conductive materials for the heating contact in a PCRAM cell.

In one embodiment of the present invention, the memory cell is a CBRAM memory cell.

In accordance with another embodiment of the present invention, the memory cell is a PCRAM memory cell.

A cell in accordance with one embodiment of the present invention can be part of an arrangement containing a plurality of memory cells arranged for example on the crosspoint between the word and the bit lines.

According to the eighth embodiment of the present invention a process of manufacturing a memory cell is provided as shown in a flow diagram 70 of FIG. 7

For example, a metallization for the cathode may be deposited on a substrate and patterned using lithographic techniques. By way of example, tungsten, TiN, TiW, TiAlN or others may be used as an electrode material for the cathode.

After having patterned the cathode, the chalcogenide material is deposited and patterned (process 72). The deposition of the chalcogenide material is done using for example reactive sputtering techniques with targets selected from for example S, Se and/or Te on the one hand and germanium, bismuth, nickel, and/or zinc on the other hand. The layer thickness of the chalcogenide material is approximately 50 nm-100 nm in this particular example. The size of the cell can be approximately 1 μm×1 μm, but both larger and smaller cells can also be prepared using the process described herein.

Thereafter, if desired, a metal, e.g., silver, may be introduced into the chalcogenide material in order to form a solid state electrolyte (process 74). The introduction of silver can take place either by illuminating a thin silver film deposited onto the chalcogenide material with light of wavelength of typically less than 500 nm or in a sputter process by using an Ag sputter target. After the formation of the solid state electrolyte, this layer may be cleaned by RF-plasma, if necessary.

Onto the layer of the chalcogenide material for a seed layer is deposited (process 76). The seed layer comprises typically copper (Cu) and optionally other material(s).

In one embodiment, the seed layer consists of Cu and a further material selected from the group consisting of Ta, W, Ti, Mo, and Ru.

The deposition of the seed layer can be done by sputtering using a Cu-target if a layer that consists essentially of Cu is desired. Alternatively, the deposition can be done using co-sputtering with a Cu-target and one or more targets of (an)other material(s) if the seed layer should contain further materials. Alternately, the deposition can done using a compound target, such as CuRu if a layer containing Cu and Ru is desired.

After the deposition of the seed layer and optionally structuring the seed layer, a partial or a complete diffusion of Cu from the seed layer into the chalcogenide layer can be performed by for example temperature treatment. In an alternative embodiment of the invention a complete diffusion of Cu from the seed layer into the chalcogenide layer can be performed by photodissolution. If, for example, the seed layer is made essentially of copper and ruthenium, after the diffusion of copper only a ruthenium layer as a seed would be left on the surface of the chalcogenide layer.

In another embodiment of the invention, seed layer contains Cu and Ru. Further materials are not necessary and a layer consisting essentially of Cu is sufficient to provide a smooth interface between the solid state electrolyte and the reactive anode. Nevertheless, it may be desirable to include further materials into the seed layer for particular purposes and application.

The thickness of the seed layer is in the range of about 0.3 nm to about 500 nm. According to another embodiment of the present invention the thickness of the seed layer is less than 1 nm.

By providing a seed layer onto the layer of a chalcogenide material, it is possible to obtain a thickness uniformity of ±about 1% of the seed layer.

It is then possible to deposit a further layer(s), for example a third layer onto the seed layer, by for example electro-chemical plating or by sputtering. The further layer(s) can, for example, serve as an anode in a CBRAM cell or as a heating contact in the PCRAM.

In one embodiment of the present invention the memory cell is a CBRAM memory cell.

In accordance to another embodiment of the present invention, the memory cell is a PCRAM memory cell.

A cell in accordance with one embodiment of the present invention can be part of an arrangement containing a plurality of memory cells arranged, for example, on the crosspoints between the word and the bit lines.

From the foregoing it will be appreciated that specific embodiments of the invention have been described herein for the purposes of illustration, but that various modifications may be made without departing from the spirit and scope of the invention. Accordingly, the invention is not limited except as by the appended claims.

What is claimed is:

1. A layer structure comprising:
a first layer comprising a chalcogenide material; and
a second layer overlying the first layer, the second layer comprising silver and another material that decreases a mobility of silver atoms or ions.

2. The layer structure according to claim 1, wherein the chalcogenide material comprises a first component selected from the group consisting of: sulfur, selenium tellurium, and combinations thereof, and a second component selected from the group consisting of: arsenic, germanium, bismuth, nickel, zinc, and combinations thereof.

3. The layer structure according to claim 1, wherein the chalcogenide material is selected from the group consisting of: GeSe, GeS, and combinations thereof.

4. The layer structure according to claim 1, wherein the first layer comprises metal ions that are mobile under the influence of an electric field.

5. The layer structure according to claim 1, wherein the first layer has a thickness in a range of about 10 nm to about 500 nm.

6. The layer structure according to claim 1, wherein the second layer further comprises tantalum.

7. The layer structure according to claim 1, wherein the second layer consists essentially of Ta and Ag.

8. The layer structure according to claim 1, wherein the second layer consists essentially of Ta and Ag, the Ta content being in a range of about 50 atomic % to about 3 atomic %.

9. The layer structure according to claim 1, wherein the second layer has a thickness of less than 100 nm.

10. The layer structure according to claim 1, wherein the second layer has a thickness uniformity of ± about 10%.

11. The layer structure according to claim 1, wherein the second layer has a thickness in a range of about 10 nm to about 100 nm.

12. The layer structure according to claim 1, further comprising a third layer overlying the second layer.

13. The layer structure according to claim 1, further comprising a third layer overlying the second layer, the third layer comprising silver.

14. The layer structure according to claim 1, further comprising a third layer overlying the second layer, the third layer consisting essentially of Ag.

15. A layer structure comprising:
a first layer comprising a chalcogenide material; and
a second seed layer overlying the first layer, the second seed layer comprising copper.

16. The layer structure according to claim 15, wherein the chalcogenide material comprises a first component selected from the group consisting of: sulfur, selenium tellurium, and combinations thereof, and a second component selected from the group consisting of: arsenic, germanium, bismuth, nickel, zinc, and combinations thereof.

17. The layer structure according to claim 15, wherein the chalcogenide material is selected from the group consisting of: GeSe, GeS, and combinations thereof.

18. The layer structure according to claim 15, wherein the first layer has a thickness in a range of about 10 nm to about 500 nm.

19. The layer structure according to claim 15, wherein the first layer comprises metal ions that are mobile under the influence of an electric field.

20. The layer structure according to claim 15, wherein the second layer further comprises a material selected from the group consisting of: Ta, W, Ti, Mo, Ru, and combinations thereof.

21. The layer structure according to claim 15, wherein the second layer consists essentially of copper.

22. The layer structure according to claim 15, wherein the second layer consists essentially of Cu and Ru.

23. The layer structure according to claim 15, further comprising a third layer overlying the second layer, wherein the second layer consists essentially of copper.

24. The layer structure according to claim 15, further comprising a third layer overlying the second layer, the third layer comprising silver.

25. The layer structure according to claim 15, further comprising a third layer overlying the second layer, the third layer consisting essentially of Ag.

26. The layer structure according to claim 15, wherein the second layer has a thickness in a range of about 0.3 nm to about 50 nm.

27. The layer structure according to claim 15, wherein the second layer has a thickness in a range of about 0.3 to about 1 nm.

28. The layer structure according to claim 15, wherein the second layer has a thickness of less than 1 nm.

29. The layer structure according to claim 15, wherein the second layer has a thickness uniformity of ± about 1%.

30. A memory cell comprising:
a first layer comprising a chalcogenide material; and
a second layer overlying the first layer, the second layer comprising silver and another material that decreases a mobility of silver atoms or ions.

31. The memory cell according to claim 30, wherein the second layer comprises tantalum.

32. The memory cell according to claim 30, wherein the second layer consists essentially of Ta and Ag.

33. The memory cell according to claim 30, wherein the second layer consists essentially of Ta and Ag, the Ta content being in a range of about 3 atomic % to about 50 atomic %.

34. The memory cell according to claim 30, wherein the second layer has a thickness in a range of about 10 nm to about 100 nm.

35. The memory cell according to claim 30, wherein the memory cell is a CBRAM memory cell.

36. The memory cell according to claim 30, wherein the memory cell is a PCRAM memory cell.

37. The memory cell according to claim 30, wherein the memory cell has a size of about 1×1 μm.

38. The memory cell according to claim 30, further comprising a third layer overlying the second layer.

39. The memory cell according to claim 30, further comprising a third layer overlying the second layer, the third layer comprising silver.

40. The memory cell according to claim 30, further comprising a third layer overlying the second layer, the third layer consisting essentially of Ag.

41. A memory cell, comprising:
a first layer comprising a chalcogenide material; and
a second seed layer overlying the first layer, the second seed layer comprising copper.

42. The memory cell according to claim 41, wherein the second layer further comprises a material selected from the group consisting of: Ta, W, Ti, Mo, Ru, and combinations thereof.

43. The memory cell according to claim 41, wherein the second layer consists essentially of copper.

44. The memory cell according to claim 41, wherein the second layer consists essentially of Cu and Ru.

45. The memory cell according to claim 41, further comprising a third layer overlying the second layer.

46. The memory cell according to claim 41, further comprising a third layer overlying the second layer, the third layer comprising silver.

47. The memory cell according to claim 41, further comprising a third layer overlying the second layer, the third layer consisting essentially of Ag.

48. The memory cell according to claim 41, wherein the second layer has a thickness in a range of about 10 nm to about 100 nm.

49. The memory cell according to claim 41, wherein the memory cell is a CBRAM memory cell.

50. The memory cell according to claim 41, wherein the memory cell is a PCRAM memory cell.

51. The memory cell according to claim 41, wherein the memory cell has a size of about 1×1 μm.

52. A method of manufacturing a layer structure, the method comprising:
depositing a first layer comprising a chalcogenide material; and
depositing a second layer on the first layer, the second layer comprising silver and another material that decreases a mobility of silver atoms or ions.

53. The method of claim 52, wherein the depositing of the second layer comprises reactive sputtering with a first sputtering target being an Ag-target and the second sputtering target being a Ta-target.

54. The method of claim 52, wherein the depositing of the second layer comprises reactive sputtering with one target, the one target comprising Ag and Ta.

55. The method of claim 52, wherein the depositing of the second layer comprises reactive sputtering with one target, the one target consisting essentially of Ag and Ta.

56. A method of manufacturing a layer structure, the method comprising:
depositing a first layer comprising a chalcogenide material; and
depositing a second seed layer on the first layer, the second layer comprising copper.

57. The method of claim 56, further comprising, after the depositing the first layer, doping the chalcogenide material with metal ions.

58. The method of claim 56, wherein the depositing of the second layer comprises reactive sputtering with a first sputtering target being a Cu-target and a second sputtering target being a target selected from the group consisting of: Ta, W, Ti, Mo, Ru, and combinations thereof.

59. The method of claim 56, wherein the depositing of the second layer comprises reactive sputtering with one target, the one target comprising Cu.

60. The method of claim 56, wherein the depositing of the second layer comprises reactive sputtering with one target, the one target consisting essentially of Ag and Ta.

61. A method of manufacturing a memory cell, the method comprising:
depositing a first layer comprising a chalcogenide material;
doping the chalcogenide material with metal ions; and
depositing a second layer on the first layer, the second layer comprising silver and another material that decreases a mobility of silver atoms or ions.

62. A method of manufacturing a layer structure, the method comprising:
depositing a first layer comprising a chalcogenide material; and
depositing a second seed layer on the first layer, wherein the second seed layer comprises copper.

63. The method of claims 62, further comprising, after the depositing the first layer, doping the chalcogenide material with metal ions.
